(19) United States
(12) Patent Application Publication
(10) Pub. No.: US 2007/0047675 A1
(43) Pub. Date: Mar. 1, 2007

(54) METHOD AND APPARATUS FOR SCALING DEMODULATED SYMBOLS FOR FIXED POINT PROCESSING

(75) Inventor: Philip J. Pietraski, Huntington Station, NY (US)

Correspondence Address: VOLPE AND KOENIG, P.C.;DEPT. ICC, UNITED PLAZA, SUITE 1600, 30 SOUTH 17TH STREET, PHILADELPHIA, PA, 19103, US

(73) Assignee: INTERDIGITAL TECHNOLOGY CORPORATION, Wilmington, DE (US)

(21) Appl. No.: 11/468,062

(22) Filed: Aug. 29, 2006

Related U.S. Application Data
(60) Provisional application No. 60/713,141, filed on Aug. 31, 2005.

(51) Int. Cl. H04L 27/06; H03D 1/04

(52) U.S. Cl. 375/340; 375/346

(57) ABSTRACT

A method and apparatus for scaling demodulated symbols for fixed-point processing are disclosed. Received data are demodulated to generate symbols. The symbols are mapped to soft bits. A signal-to-interference ratio (SIR) is estimated on a current transmission. A scaling factor is then generated for retransmissions based on a ratio of the SIR of the current transmission to the SIR of the latest new transmission of the same process. The soft bits are scaled with the scaling factor and the scaled soft bits are decoded. The scaling allows for reduction of the retransmission buffer size.

### CROSS REFERENCE TO RELATED APPLICATION

This application claims the benefit of U.S. Provisional Application No. 60/713,141 filed Aug. 31, 2005, which is incorporated by reference as if fully set forth.

### FIELD OF INVENTION

The present invention is related to a wireless communication system. More particularly, the present invention is related to a method and apparatus for scaling demodulated symbols.

### BACKGROUND

When signals are transmitted over a wireless channel, both the signal-to-noise ratio (SNR) and power, (or amplitude), of the signals vary at the receiver due to fading. Automatic gain control (AGC) is performed at the receiver to compensate for the variation. However, AGC only partially compensates for the variation in the signal power since the AGC reaction time is much longer than the fading times, and because AGC operates on the entire received power, not just the desired signal's power. Therefore, as the signal fades, conventional receivers, (e.g., Rake receivers), produce demodulated symbols amplitudes of which depend on the current fading characteristic of the channel. Thus, the dynamic range of the fixed-point design needs to accommodate this additional variation.

Equalizer based receivers have similar problems as the pilot/data power ratio changes. Since the signal-to-interference ratio (SIR) variation can be very large, (e.g., 20 dB), the fixed-point implementation of the signal processing components after demodulation needs to have as much as a 3-4 bit increase in word size than what is necessary for a fading-free condition.

For hybrid automatic repeat request (H-ARQ) operation, a receiver decodes received data blocks and sends acknowledgement (ACK) or non-acknowledgement (NACK) feedback to a transmitter, depending whether or not the decoding succeeds. The transmitter retransmits the failed transmission in accordance with the feedback. The receiver includes a retransmission buffer to store previous transmissions that failed and the subsequent retransmission may be combined with a previous failed transmission stored in the buffer. Because transmissions can have very different transmitted energy per symbol and because fading conditions can be very different, the fixed-point requirements for different transmissions may be very different. This leads to an increased word size requirement on the retransmission buffer.

Therefore, it is desirable to have a solution for having to increase word size to accommodate a large variation in the scaling of data prior to decoding, and reducing the size of retransmission buffers for H-ARQ systems.

### SUMMARY

The present invention is related to a method and apparatus for scaling demodulated symbols for fixed-point processing. Received data is demodulated to generate symbols. The symbols are mapped to soft bits. An SIR is estimated on a current transmission. A scaling factor is then generated for retransmissions based on a ratio of the SIR of the current transmission and the SIR of the latest new transmission from the same process. The soft bits are scaled based on the scaling factor and the scaled soft bits are decoded. The scaling relative to the latest new transmission allows for reduction of the retransmission buffer size.

### BRIEF DESCRIPTION OF THE DRAWINGS

A more detailed understanding of the invention may be had from the following description of a preferred example, given by way of example and to be understood in conjunction with the accompanying drawing wherein:

FIG. 1 is a flow diagram of a process of scaling demodulated symbols with a scaling factor for a fixed-point processing in accordance with the present invention; and

FIG. 2 is a block diagram of an apparatus for scaling demodulated symbols with a scaling factor for fixed-point processing in accordance with the present invention.

### DETAILED DESCRIPTION OF THE PREFERRED EMBODIMENTS

The present invention may be implemented in a wireless transmit/receive unit (WTRU) or a base station. The terminology “WTRU” includes but is not limited to a user equipment, a mobile station, a fixed or a mobile subscriber unit, a pager, or any other type of device capable of operating in a wireless environment. The terminology “base station” includes but is not limited to a Node-B, a site controller, an access point or any other type of interfacing device in a wireless environment.

The method of the present invention may be implemented in various types of systems including, but not limited to, IEEE 802.xx, third generation partnership project (3GPP) time division duplex (TDD) and frequency division duplex (FDD), time division synchronous code division multiple access (TDSCDMA), orthogonal frequency division multiplex (OFDM), CDMA2000, or the like. The present invention is preferably applied to a fixed point processing. However, the present invention may also be applied to a floating point processing.

The features of the present invention may be incorporated into an integrated circuit (IC) or be configured in a circuit comprising a multitude of interconnecting components. The implementation may be in the form of an application specific integrated circuit (ASIC) and/or a digital signal processor (DSP).

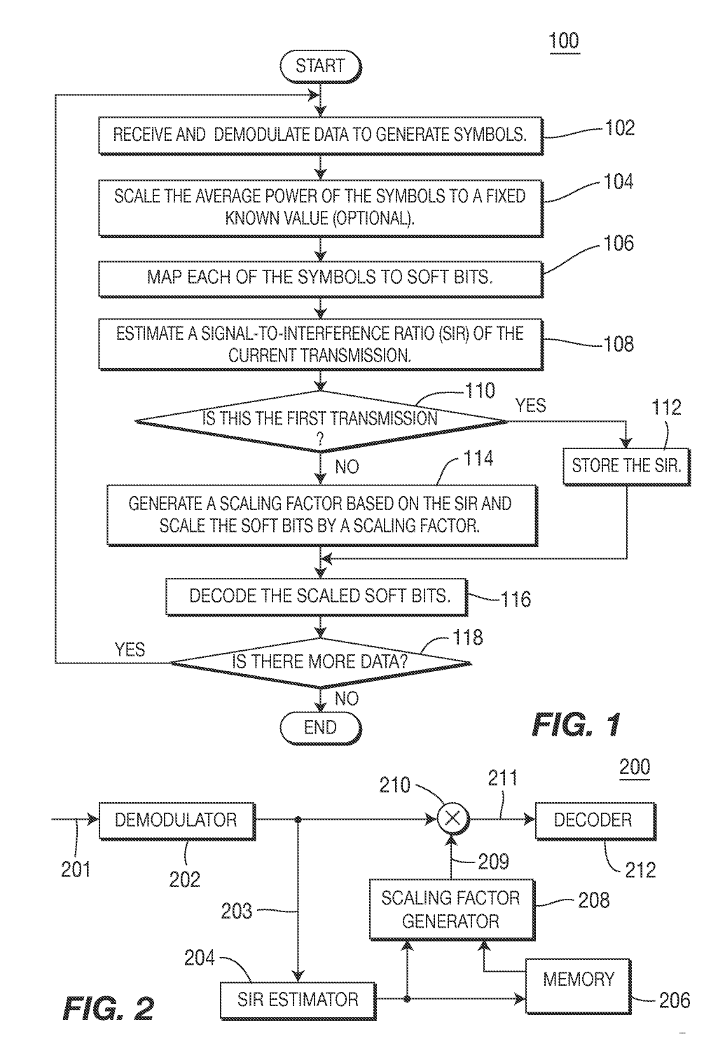

FIG. 1 is a flow diagram of a process 100 of scaling demodulated symbols with a scaling factor for fixed-point processing in accordance with the present invention. Transmitted data is received and demodulated to generate symbols (step 102). The average power of the symbols may optionally be scaled to have a fixed known value, (i.e., the symbols are scaled to have a fixed constant power), (step 104). For example, this may be accomplished by collecting a group of symbols and measuring the average power of the symbols in that group, taking the inverse of square root of that power measurement, and multiplying each symbol in the group by the inverse of square root of the power measurement. This results in a group of symbols that have been scaled to have unit power. Each of the symbols is then mapped to soft bits (step 106). In mapping the symbols to soft bits, each symbol is represented by a predetermined number of bits in the fixed-point system. The SIR of the current transmission is estimated (step 108). It is then determined whether the current transmission is the first transmission, (i.e., a new transmission), (step 110). “First transmission”, (or “new transmission”), means that it is the first time that a particular data packet has been transmitted for a given hybrid automatic repeat request (H-ARQ) process. When the reception of the “first transmission” of a packet fails, the packet is re-transmitted. If the current transmission is a new transmission for the H-ARQ process, no additional scaling is performed and the SIR of the new transmission is stored in a memory (step 112). The soft bits are then decoded (step 116).

If, in step 110, it is determined that the current transmission is not a new transmission for the given H-ARQ process, (i.e., the current transmission is a retransmission of a previous failed transmission), a scaling factor is generated based on the SIR of the current transmission and the SIR of the last new transmission for the same H-ARQ process, and the soft bits are scaled by a scaling factor (step 114). The scaling factor is generated based on the ratio of SIR(N)/SIR(1), where SIR(1) is the SIR of the last new transmission for a given H-ARQ process and SIR(N) is the SIR of the N-th subsequent transmission of the same H-ARQ process. The scaled soft bits are then decoded (step 116). If it is determined at step 118 that there is more data, the process 100 returns to step 102 to receive and demodulate subsequent transmissions of data.

The scaling is performed to match the bit-width of the decoder so over-specification of the bit-width is not necessary in accordance with the present invention. The full dynamic range of the data after scaling is proportional to the change in an SIR from one transmission to subsequent retransmissions, rather than the full dynamic range of the SIR due to fading and transmission symbol power changes. Although some additional bit-width growth may occur as retransmissions accumulate in the retransmission buffer, it is much less than full range of possible SIR and is not likely to lead to substantial degradation.

The present invention may be applied to H-ARQ or non-H-ARQ transmissions. In the case of non-H-ARQ transmission, the maximum number of transmissions is set to zero. In accordance with the present invention, the size of the memory required for the retransmission buffer may be reduced by a factor of approximately ⅓ to ½, depending on the SIR range. Since the retransmission buffer may be very large, (e.g., 172,800 soft bits for high category 3GPP WTRUs), there would be a substantial reduction in memory requirements. Assuming that a 6-bit representation is needed in a conventional method, but 2 bits are reduced in accordance with the present invention, 345,600 bits, (i.e., 172,800×2), may be saved in the foregoing example. Decoder complexity and internal memory would also be reduced due to the smaller word size.

FIG. 2 is a block diagram of an apparatus 200 for scaling demodulated symbols with a scaling factor for fixed-point processing in accordance with the present invention. The apparatus 200 includes a demodulator 202, an SIR estimator 204, a memory 206, a scaling factor generator 208, a multiplier 210 and a decoder 212. The demodulator 202 receives, and demodulates, symbol data 201 and maps each of the symbols 201 to soft bits 203. The demodulator 202 may scale the symbols 201 to have fixed constant power. The SIR estimator 204 estimates an SIR on a current transmission. If the transmission is a new transmission for a H-ARQ process, then the SIR is stored in the memory 206. The scaling factor generator 208 generates a scaling factor 209 based on the ratio of the SIR of the current transmission to the SIR of the last new transmission from the same H-ARQ process. The scaling factor 209 is then applied to the soft bits 203 by the multiplier 210 to generate scaled soft bits 211. The decoder 212 then decodes the scaled soft bits 211.

In cases where packet duration is long compared to fading rates or when it is desirable to reduce computational complexity in the SIR estimation, the SIR may be computed based on a fraction of the packet. For example, the packet is broken up into slots, and the scaling is performed on a slot-by-slot basis, (rather than packet-by-packet basis). The scaling factor is computed in the same way except each slot is treated as a separate transmission and only the SIR on the fist slot of a new transmission packet is saved in the memory. All slots from the new packet except the first slot are scaled relative to the SIR of the first slot. All slots of retransmission packets are scaled relative to the first slot of the last new transmission from the same H-ARQ process.

Although the features and elements of the present invention are described in the preferred embodiments in particular combinations, each feature or element can be used alone without the other features and elements of the preferred embodiments or in various combinations with or without other features and elements of the present invention.

What is claimed is:

1. A method of scaling demodulated data symbols for processing, the method comprising:
receiving and demodulating data to generate symbols;
mapping each of the symbols to soft bits;
estimating a signal-to-interference ratio (SIR) of a current transmission;
generating a scaling factor based on a ratio of the SIR of the current transmission to an SIR of a previous new transmission;
scaling the soft bits with the scaling factor; and
decoding the scaled soft bits.

2. The method of claim 1 further comprising scaling the symbols to have a fixed constant power before mapping the symbols to the soft bits.

3. The method of claim 2 wherein the symbols are scaled to have a unit power.

4. The method of claim 1 wherein a transmission is divided into a plurality of slots, the SIR is estimated on a slot-by-slot basis, and the scaling factor is generated based on a ratio of the SIR of each of the slots of the current transmission to an SIR of a first slot of a previous new transmission.

5. The method of claim 1 wherein the symbols are mapped to a fixed number of bits.

6. An apparatus for scaling demodulated data symbols for processing, the apparatus comprising:
a demodulator for receiving and demodulating data to generate symbols and mapping each of the symbols to soft bits;
a signal-to-interference ratio (SIR) estimator for estimating an SIR;
a memory for storing the SIR;
a scaling factor generator for generating a scaling factor based on a ratio of the SIR of a current transmission to an SIR of a previous new transmission;
a multiplier for multiplying the soft bits with the scaling factor to generate scaled soft bits; and
a decoder for decoding the scaled soft bits.

7. The apparatus of claim 6 wherein the demodulator scales the symbols to have a fixed constant power.

8. The apparatus of claim 7 wherein the symbols are scaled to have a unit power.

9. The apparatus of claim 6 wherein a transmission is divided into a plurality of slots, the SIR estimator estimates the SIR on a slot-by-slot basis, and the scaling factor generator generates the scaling factor based on a ratio of the SIR of each of the slots of the current transmission to an SIR of a first slot of a previous new transmission.

10. The apparatus of claim 6 wherein the symbols are mapped to a fixed number of bits.

11. The apparatus of claim 6 wherein the apparatus is a wireless transmit/receive unit (WTRU).

12. The apparatus of claim 6 wherein the apparatus is a base station.

13. The apparatus of claim 6 wherein the apparatus is an integrated circuit (IC).

14. A method of scaling demodulated data symbols for processing, the method comprising:
receiving and demodulating data to generate symbols;
mapping each of the symbols to soft bits;
estimating a signal-to-interference ratio (SIR) from the soft bits on a current transmission;
determining if the current transmission is a first transmission;
if the current transmission is a first transmission, storing the SIR and decoding the soft bits; and
if the current transmission is not a first transmission, generating a scaling factor based on a ratio of the SIR on the current transmission and an SIR on the first transmission, scaling the soft bits with the scaling factor and decoding the scaled soft bits.

15. The method of claim 14 further comprising scaling the symbols to have a fixed constant power.

16. The method of claim 15 wherein the symbols are scaled to have a unit power.

17. The method of claim 14 wherein a transmission is divided into a plurality of slots, the SIR is estimated on a slot-by-slot basis, and the scaling factor is generated based on a ratio of the SIR of each of the slots of the current transmission to an SIR of a first slot of the first transmission.

18. The method of claim 14 wherein the symbols are mapped to a fixed number of bits.

19. An apparatus for scaling demodulated data symbols for processing, the apparatus comprising:
a demodulator for receiving and demodulating data to generate symbols and mapping each of the symbols to soft bits;
a signal-to-interference ratio (SIR) estimator for estimating an SIR from the soft bits on a current transmission;
a memory for storing an SIR of a first transmission;
a scaling factor generator for generating a scaling factor based on a ratio of the SIR of a current transmission to an SIR of the first transmission;
a multiplier for multiplying the soft bits with the scaling factor to generate scaled soft bits; and
a decoder for decoding the scaled soft bits.

20. The apparatus of claim 19 wherein the demodulator scales the symbols to have a fixed constant power.

21. The apparatus of claim 20 wherein the symbols are scaled to have a unit power.

22. The apparatus of claim 19 wherein a transmission is divided into a plurality of slots, the SIR estimator estimates the SIR on a slot-by-slot basis, and the scaling factor generator generates the scaling factor based on a ratio of the SIR of each of the slots of the current transmission to an SIR of a first slot of the first transmission.

23. The apparatus of claim 19 wherein the symbols are mapped to a fixed number of bits.

24. The apparatus of claim 19 wherein the apparatus is a wireless transmit/receive unit (WTRU).

25. The apparatus of claim 19 wherein the apparatus is a base station.

26. The apparatus of claim 19 wherein the apparatus is an integrated circuit (IC).
